(19) United States
(12) Patent Application Publication
(10) Pub. No.: US 2009/0117408 A1
(43) Pub. Date: May 7, 2009

(54) PERPENDICULAR MAGNETIC RECORDING DISK AND METHOD OF MANUFACTURING THE SAME

(75) Inventors: Teiichiro Umezawa, Singapore (SG); Lianjun Wu, Singapore (SG); Yoshiaki Sonobe, Singapore (SG); Chikara Takasu, Singapore (SG); Takahiro Onoue, Singapore (SG)

Correspondence Address: SUGHRUE MION, PLLC, 2100 PENNSYLVANIA AVENUE, N.W., SUITE 800, WASHINGTON, DC, 20037, US

(73) Assignees: HOYA CORPORATION, Shinjuku-ku , Tokyo (JP); HOYA MAGNETICS SINGAPORE PTE. LTD., Singapore (SG)

(21) Appl. No.: 12/295,573

(22) PCT Filed: Mar. 31, 2007
(86) PCT No.: PCT/JP2007/057318

§ 371 Date: Sep. 30, 2008

(30) Foreign Application Priority Data
Mar. 31, 2006 (JP) 2006-100319

(51) Int. Cl. G11B 5/66; C23C 14/35

(52) U.S. Cl. 428/827; 204/192.15

(57) ABSTRACT

To provide a perpendicular magnetic recording disk having a film structure that improves overwrite characteristics (O/W) while maintaining a coercive force (Hc) high enough not to affect heat fluctuation resistance, and a manufacturing method thereof.

A magnetic disk for use in perpendicular magnetic recording, having at least an underlayer, a first magnetic recording layer, and a second magnetic recording layer on a substrate in the order named, characterized in that the first magnetic recording layer and the second magnetic recording layer are each a ferromagnetic layer of a granular structure containing a nonmagnetic substance forming grain boundary portions between crystal grains containing at least Co (cobalt) and, given that the content of the nonmagnetic substance in the first magnetic recording layer is A mol % and the content of the nonmagnetic substance in the second magnetic recording layer is B mol %, A<B.

### TECHNICAL FIELD

This invention relates to a perpendicular magnetic recording medium adapted to be mounted in a perpendicular magnetic recording type HDD (hard disk drive) or the like.

### BACKGROUND ART

Various information recording techniques have been developed following the increase in volume of information processing in recent years. Particularly, the areal recording density of HDDs (hard disk drives) using the magnetic recording technique has been increasing at an annual rate of about 100%. Recently, the information recording capacity exceeding 60 GB has been required per 2.5-inch magnetic disk adapted for use in a HDD or the like. In order to satisfy such a requirement, it is necessary to realize an information recording density exceeding 100 Gbits/inch². In order to achieve the high recording density in a magnetic disk for use in a HDD or the like, it is necessary to reduce the size of magnetic crystal grains forming a magnetic recording layer serving to record information signals, and further, to reduce the thickness of the layer. However, in the case of conventionally commercialized magnetic disks of the in-plane magnetic recording type (also called the longitudinal magnetic recording type or the horizontal magnetic recording type), as a result of the reduction in size of magnetic crystal grains, there has arisen a so-called thermal fluctuation phenomenon where the thermal stability of recorded signals is degraded due to superparamagnetism so that the recorded signals are lost, which has thus become an impeding factor for the increase in recording density of the magnetic disks.

In order to solve this impeding factor, magnetic disks of the perpendicular magnetic recording type have been proposed in recent years. In the case of the perpendicular magnetic recording type, as different from the case of the in-plane magnetic recording type, the easy magnetization axis of a magnetic recording layer is adjusted so as to be oriented in a direction perpendicular to the surface of a substrate. As compared with the in-plane magnetic recording type, the perpendicular magnetic recording type can suppress the thermal fluctuation phenomenon and thus is suitable for increasing the recording density. For example, Japanese Unexamined Patent Application Publication (JP-A) No. 2002-92865 (Patent Document 1) discloses a technique about a perpendicular magnetic recording medium having an underlayer, a Co-based perpendicular magnetic recording layer, and a protective layer that are formed on a substrate in the order named. Further, U.S. Pat. No. 6,468,670 Specification (Patent Document 2) discloses a perpendicular magnetic recording medium having a configuration in which an exchange-coupled artificial lattice film continuous layer (exchange-coupled layer) is adhered to a granular recording layer.
Patent Document 1: Japanese Unexamined Patent Application Publication (JP-A) No. 2002-92865
Patent Document 2: U.S. Pat. No. 6,468,670 Specification

### DISCLOSURE OF THE INVENTION

### Problem to be Solved by the Invention

Also in the case of the perpendicular magnetic recording medium, like in the case of the in-plane magnetic recording medium, the recording density of the magnetic disk is improved mainly by reducing noise in a magnetization transition region of a magnetic recording layer. For the noise reduction, it is necessary to improve the crystal orientation of the magnetic recording layer and to reduce the crystal grain size and the magnitude of magnetic interaction. That is, in order to increase the recording density of the medium, it is desirable to equalize and reduce the crystal grain size in the magnetic recording layer and, further, to provide a segregated state where individual magnetic crystal grains are magnetically separated.

In the meantime, the Co-based perpendicular magnetic recording layer disclosed in Patent Document 1, particularly a CoPt-based perpendicular magnetic recording layer, has a high coercive force (Hc) and can cause a reversed domain nucleation magnetic field (Hn) to be a small value less than zero and, therefore, the resistance against thermal fluctuation can be improved and a high S/N ratio can be achieved, which is thus preferable. Further, by causing an element such as Cr to be contained in such a perpendicular magnetic recording layer, Cr can be segregated at grain boundary portions of the magnetic crystal grains to block the exchange interaction between the magnetic crystal grains, thereby contributing to increasing the recording density.

Further, by adding an oxide such as SiO₂ to the CoPt-based perpendicular magnetic recording layer, it is possible to form an excellent segregated structure without impeding the epitaxial growth of CoPt. That is, by segregating the oxide such as SiO₂ at the grain boundaries to reduce the crystal grain size and further to reduce the magnetic interaction between the magnetic grains, the low noise is achieved.

However, if the size of the magnetic grains is excessively reduced, the thermal fluctuation phenomenon arises as a problem like in the case of the in-plane magnetic recording medium. In order to avoid this thermal fluctuation problem, the following methods have been employed so far. One is a method that increases an anisotropy constant (Ku) of a magnetic layer by optimizing the composition of the magnetic layer, thereby improving the coercive force of a medium. The other is a method that improves the crystal orientation of a magnetic layer by optimizing materials of a seed layer and an underlayer or optimizing the film structures of them, thereby improving the coercive force.

On the other hand, although the improvement in coercive force makes it possible that recorded signals do not easily suffer the influence of thermal fluctuation, but it simultaneously makes writing by a magnetic head difficult. In future, the magnetic grain size will be reduced more and more with an increase in recording density, so that there will be no alternative but to further increase the coercive force of a medium. There is a possibility that the increase in coercive force ultimately makes writing impossible.

This invention aims to solve such problems and has an object to provide a perpendicular magnetic recording disk having a film structure that improves overwrite characteristics (O/W) while maintaining a coercive force (Hc) high enough not to affect heat fluctuation resistance, and a manufacturing method thereof.

### Means for Solving the Problem

In order to solve the above-mentioned problem, as a representative structure of a perpendicular magnetic recording disk according to this invention, there is provided a perpendicular magnetic recording disk for use in perpendicular magnetic recording, comprising at least an underlayer, a first magnetic recording layer, and a second magnetic recording layer on a substrate in the order named, wherein the first magnetic recording layer and the second magnetic recording layer are each a ferromagnetic layer of a granular structure containing a nonmagnetic substance forming a grain boundary portion between crystal grains containing at least cobalt (Co), and given that the content of the nonmagnetic substance in the first magnetic recording layer is A mol % and the content of the nonmagnetic substance in the second magnetic recording layer is B mol %, A<B.

The nonmagnetic substance may be any substance as long as it is a substance that can form grain boundary portions around magnetic grains so as to suppress or block the exchange interaction between the magnetic grains and that is a nonmagnetic substance not solid-soluble to cobalt (Co). For example, chromium (Cr), oxygen (O), and oxides such as silicon oxide (SiOx), chromium oxide (CrO₂), titanium oxide (TiO₂), zirconium oxide (ZrO₂), and tantalum oxide (Ta₂O₅) can be cited as examples.

The content of the nonmagnetic substance in the first magnetic recording layer is preferably 8 mol % to 20 mol % and more preferably 8 mol % to 12 mol %. The content of the nonmagnetic substance in the second magnetic recording layer is preferably 8 mol % to 20 mol % and more preferably 10 mol % to 14 mol %. This is because if it is 8 mol % or less, a sufficient compositional separation (segregation) structure cannot be formed and thus a high S/N ratio cannot be obtained. Further, this is because if it is 20 mol % or more, it is difficult for Co to form hcp crystals, so that sufficient perpendicular magnetic anisotropy cannot be obtained and thus high Hn cannot be obtained. The magnetic recording layers are preferably formed by a sputtering method. A DC magnetron sputtering method is particularly preferable because uniform film formation is enabled.

In order to obtain high Hn, the total thickness of the first magnetic recording layer and the second magnetic recording layer is preferably 15 nm or less.

An orientation control layer having a bcc-structure-containing amorphous or fcc structure is preferably provided between the substrate and the underlayer. The orientation control layer is a layer having a function of controlling the orientation of crystal grains of the underlayer. The orientation control layer can be formed of a material such as, for example, Ta, Nb, a Ni-based alloy such as NiP, a Co-based alloy such as CoCr, a nonmagnetic layer containing Ta or Ti, Pd, or Pt.

An amorphous soft magnetic layer is preferably provided between the substrate and the underlayer. In this invention, the soft magnetic layer is not particularly limited as long as it is formed of a magnetic body that exhibits the soft magnetic properties and, for example, use can be made of an Fe-based soft magnetic material such as FeTaC-based alloy, FeTaN-based alloy, FeNi-based alloy, FeCoB-based alloy, or FeCo-based alloy, a Co-based soft magnetic material such as CoTaZr-based alloy or CoNbZr-based alloy, an FeCo-based alloy soft magnetic material, or the like.

Further, the soft magnetic layer preferably has as its magnetic property a coercive force (Hc) of 0.01 to 80 oersteds (Oe) and more preferably 0.01 to 50 oersteds. Further, it preferably has as its magnetic property a saturation magnetic flux density (Bs) of 500 emu/cc to 1920 emu/cc. The thickness of the soft magnetic layer is preferably 10 nm to 1000 nm and more preferably 20 nm to 150 nm. When it is less than 10 nm, there is a case where it becomes difficult to form a suitable magnetic circuit between magnetic head—perpendicular magnetic recording layer—soft magnetic layer, while, when it exceeds 1000 nm, there is a case where the surface roughness increases. Further, when it exceeds 1000 nm, there is a case where the sputtering film formation becomes difficult.

The substrate is preferably an amorphous glass. When magnetic field annealing is necessary for controlling magnetic domains of the soft magnetic layer, the substrate is preferably a glass because it is excellent in heat resistance. As the glass for the substrate, an amorphous glass or a crystallized glass can be used and, for example, there can be cited an aluminosilicate glass, an aluminoborosilicate glass, a soda lime glass, or the like. Among them, the aluminosilicate glass is preferable. When the soft magnetic layer is amorphous, the substrate is preferably the amorphous glass. When a chemically strengthened glass is used, the rigidity is high, which is thus preferable.

The surface roughness of the main surface of the substrate is preferably 6 nm or less in Rmax and 0.6 nm or less in Ra. By providing such a smooth surface, a gap between perpendicular magnetic recording layer—soft magnetic layer can be set constant so that it is possible to form a suitable magnetic circuit between magnetic head—perpendicular magnetic recording layer—soft magnetic layer.

As a representative structure of a method of manufacturing a perpendicular magnetic recording disk according to this invention, there is provided a method of manufacturing a perpendicular magnetic recording disk for use in perpendicular magnetic recording, the disk comprising at least an underlayer, a first magnetic recording layer, and a second magnetic recording layer on a substrate in the order named, the method comprising forming, as the first magnetic recording layer, a ferromagnetic layer of a granular structure in which a nonmagnetic substance is segregated between magnetic grains containing at least cobalt (Co), and forming, as the second magnetic recording layer, a ferromagnetic layer of a granular structure in which a nonmagnetic substance is segregated between magnetic grains containing at least cobalt (Co), wherein, given that the content of the nonmagnetic substance in the first magnetic recording layer is A mol % and the content of the nonmagnetic substance in the second magnetic recording layer is B mol %, A<B. A sputtering method, particularly a DC magnetron sputtering method, can be suitably used for forming the magnetic recording layers.

### EFFECT OF THE INVENTION

According to this invention, it is possible to improve the overwrite characteristics while maintaining the coercive force of magnetic recording layers, without adding a large change to the manufacturing process. Therefore, even in a future increase in density, it is possible to improve the write characteristics while avoiding the problem of thermal fluctuation.

### BRIEF DESCRIPTION OF THE DRAWINGS

FIG. 1 is a diagram for explaining the configuration of a perpendicular magnetic recording medium according to a first embodiment.

FIG. 2 is an exemplary diagram for explaining the vicinity of magnetic recording layers.

FIG. 3 is a diagram showing the relationship between overwrite characteristics and coercive force when the thicknesses of the first and second magnetic recording layers are changed.

FIG. 4 is a diagram for explaining the configuration of a perpendicular magnetic recording medium according to a second embodiment.

FIG. 5 is a diagram showing the relationship between overwrite characteristics and coercive force when the thicknesses of first and second magnetic recording layers according to the second embodiment are changed.

### DESCRIPTION OF SYMBOLS

1 disk substrate
2 adhesive layer
3 soft magnetic layer
4 orientation control layer
5a, 5b underlayers
6 first magnetic recording layer
6a magnetic grain
6b silicon oxide
7 second magnetic recording layer
7a magnetic grain
7b silicon oxide
8 coupling control layer
9 exchange energy control layer
10 medium protective layer
11 lubricating layer
10 medium protective layer
11 lubricating layer
23 soft magnetic layer
23a first soft magnetic layer
23b spacerlayer
23c second soft magnetic layer
24 orientation control layer
26 onset layer
27 first magnetic recording layer
28 second magnetic recording layer
29 auxiliary recording layer

### BEST MODE FOR CARRYING OUT THE INVENTION

### First Embodiment

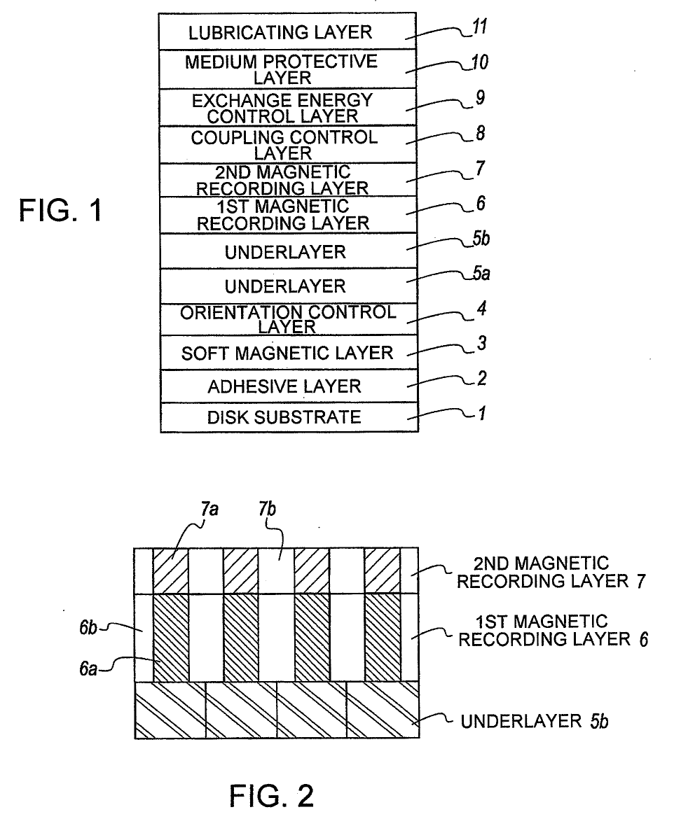

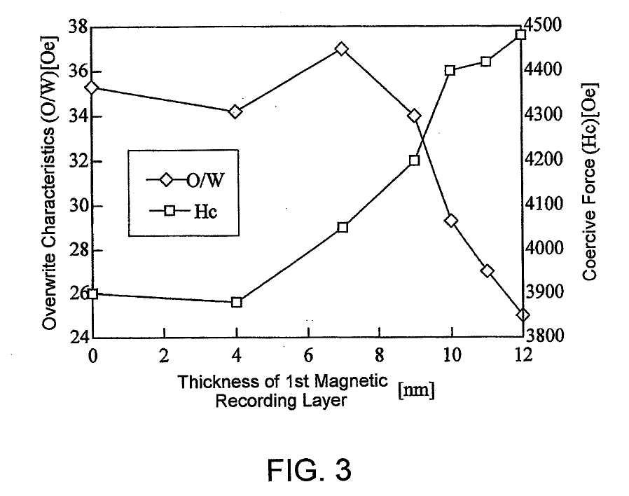

A first embodiment of a perpendicular magnetic recording medium according to this invention will be described with reference to the drawings. FIG. 1 is a diagram for explaining the configuration of the perpendicular magnetic recording medium according to the first embodiment, FIG. 2 is an exemplary diagram for explaining the vicinity of magnetic recording layers, and FIG. 3 is a diagram showing the relationship between overwrite characteristics and coercive force when the thicknesses of the first and second magnetic recording layers are changed. Numerical values given in the following embodiment are only examples for facilitating the understanding of this invention and are not intended to limit this invention unless otherwise stated.

The perpendicular magnetic recording medium shown in FIG. 1 comprises a disk substrate 1, an adhesive layer 2, a soft magnetic layer 3, an orientation control layer 4, an underlayer 5a, an underlayer 5b, a first magnetic recording layer 6, a second magnetic recording layer 7, a coupling control layer 8, an exchange energy control layer 9 (continuous layer), a medium protective layer 10, and a lubricating layer 11.

At first, an amorphous aluminosilicate glass was molded into a disk shape by direct press, thereby producing a glass disk. This glass disk was ground, polished, and chemically strengthened in sequence, thereby obtaining the smooth nonmagnetic disk substrate 1 in the form of a chemically strengthened glass disk. The disk diameter was 65 mm. The surface roughness of the main surface of the disk substrate 1 was measured by an AFM (atomic force microscope) and it was a smooth surface shape with Rmax of 4.8 nm and Ra of 0.42 nm. Rmax and Ra follow Japanese Industrial Standard (JIS).

Using an evacuated film forming apparatus, the layers from the adhesive layer 2 to the exchange energy control layer 9 were formed in sequence on the obtained disk substrate 1 in an Ar atmosphere by a DC magnetron sputtering method and then the medium protective layer 10 was formed by a CVD method. Thereafter, the lubricating layer 11 was formed by a dip coating method. In terms of high productivity, it is also preferable to use an in-line type film forming method. Hereinbelow, the structures and manufacturing methods of the respective layers will be described.

The adhesive layer 2 was formed using a Ti-alloy target so as to be a Ti-alloy layer of 10 nm. By forming the adhesive layer 2, the adhesion between the disk substrate 1 and the soft magnetic layer 3 can be improved and, therefore, it is possible to prevent stripping of the soft magnetic layer 3. As a material of the adhesive layer 2, use can be made of, for example, a Ti-containing material. In terms of practical use, the thickness of the adhesive layer is preferably set to 1 nm to 50 nm.

The soft magnetic layer 3 was formed using a CoTaZr target so as to be an amorphous CoTaZr layer of 50 nm.

The orientation control layer 4 has a function of protecting the soft magnetic layer 3 and a function of facilitating miniaturization of crystal grains of the underlayer 5a. As the orientation control layer 4, an amorphous layer of Ta was formed to a thickness of 3 nm using a Ta target.

The underlayers 5a and 5b form a two-layer structure made of Ru. By forming Ru on the upper layer side at an Ar gas pressure higher than that used when forming Ru on the lower layer side, the crystal orientation can be improved.

Using a hard magnetic target made of CoCrPt and silicon oxide (SiO₂) as an example of a nonmagnetic substance, the first magnetic recording layer 6 with an hcp crystal structure of 9 nm was formed. The first magnetic recording layer can be suitably set in a range of 7 nm to 15 nm. The composition of the target for forming the first magnetic recording layer 6 is 91 (mol %) CoCrPt and 9 (mol %) SiO₂.

Likewise, using a hard magnetic target made of CoCrPt and silicon oxide (SiO₂) as an example of a nonmagnetic substance, the second magnetic recording layer 7 with an hcp crystal structure of 3 nm was formed. The second magnetic recording layer 7 can be suitably set in a range of 0.5 nm to 5 nm. The composition of the target for forming the second magnetic recording layer 7 is 90 (mol %) CoCrPt and 10 (mol %) SiO₂.

That is, given that the content of Si in the first magnetic recording layer 6 is A mol % and the content of Si in the second magnetic recording layer 7 is B mol %, A>B (the first magnetic recording layer 6 contains more Si).

The coupling control layer 8 was formed by a Pd (palladium) layer. The coupling control layer 8 can be formed by a Pt layer instead of the Pd layer. The thickness of the coupling control layer 8 is preferably 2 nm or less and more preferably 0.5 to 1.5 nm.

The exchange energy control layer 9 is in the form of alternately layered films of CoB and Pd and was formed in a low Ar gas. The thickness of the exchange energy control layer 9 is preferably 1 to 8 nm and more preferably 3 to 6 nm.

The medium protective layer 10 was formed by film formation of carbon by the CVD method while maintaining a vacuum. The medium protective layer 10 is a protective layer for protecting the perpendicular magnetic recording layer from an impact of a magnetic head. Since, in general, carbon formed into a film by the CVD method is improved in film hardness as compared with that by the sputtering method, it is possible to protect the perpendicular magnetic recording layer more effectively against the impact from the magnetic head.

The lubricating layer 11 was formed of PFPE (perfluoropolyether) by the dip coating method. The thickness of the lubricating layer 11 is about 1 nm.

Through the manufacturing process described above, the perpendicular magnetic recording medium was obtained. The first magnetic recording layer 6 and the second magnetic recording layer 7 in the obtained perpendicular magnetic recording disk were analyzed in detail by the use of a transmission electron microscope (TEM) and they each had a granular structure. Specifically, it was confirmed that grain boundary portions made of silicon oxide were formed between crystal grains of the hcp crystal structure containing Co.

Herein, as shown in FIG. 2, magnetic grains 6a (Co-based alloy) of the first magnetic recording layer 6 and magnetic grains 7a (Co-based alloy) of the second magnetic recording layer 7 are crystallographically connected to Ru of the underlayer 5b. This is because the magnetic grains 6a and 7a and silicon oxides 6b and 7b of the first and second magnetic recording layers 6 and 7 continuously grow, respectively.

For comparison, perpendicular magnetic recording media were manufactured by changing the thickness of the first magnetic recording layer 6 from 0 to 12 nm while the sum of the thicknesses of the first magnetic recording layer 6 and the second magnetic recording layer 7 was set to 12 nm, and the magnetostatic properties of the obtained perpendicular magnetic recording disks were measured and evaluated using the Kerr effect. FIG. 3 shows changes in coercive force (Hc) and overwrite characteristics (O/W) when the ratio between the thicknesses of the first magnetic recording layer 6 and the second magnetic recording layer 7 is changed. When the first magnetic recording layer 6 is 0 nm, the second magnetic recording layer 7 is 12 nm and thus it is shown that substantially only the second magnetic recording layer 7 is formed. Likewise, when the first magnetic recording layer 6 is 12 nm, the second magnetic recording layer 7 is 0 nm and thus it is shown that substantially only the first magnetic recording layer 6 is formed.

As shown in FIG. 3, it is seen that when the ratio between the thicknesses of the first magnetic recording layer 6 and the second magnetic recording layer 7 is changed, the overwrite characteristics and the coercive force change. Further, it is seen that, in a specific thickness range, the overwrite characteristics can be improved while maintaining the coercive force. For example, as compared with the case of only the first magnetic recording layer 6 (when the thickness of the first magnetic recording layer 6 is 12 nm: plot at the right end in the figure), there is observed an improvement in overwrite characteristics of about 9 [dB] at maximum when the thickness of the layer is 7 nm.

In due consideration, in the perpendicular magnetic recording medium according to the first embodiment, since the second magnetic recording layer 7 contains more nonmagnetic substance, the crystal grains of the hcp crystal structure containing Co are smaller in the second magnetic recording layer 7. Therefore, by increasing the thickness of the second magnetic recording layer 7, the overwrite characteristics are improved while the coercive force is reduced. However, it is considered that, by setting the thickness of the second magnetic recording layer 7 at an appropriate ratio, a magnetization transition first starts in the front-side second magnetic recording layer 7 due to a write magnetic field of a magnetic head and, induced by this, a magnetization transition also occurs in the first magnetic recording layer 6. It is considered that when the magnetic field is not applied from the magnetic head, a high coercive force is exhibited by the large magnetic grains of the first magnetic recording layer 6. That is, by configuring such that the magnetic recording layers form the two-layer structure and the second magnetic recording layer on the surface layer side contains more nonmagnetic substance and, further, by setting the appropriate ratio of the layer thicknesses, the overwrite characteristics (O/W) can be improved while maintaining the coercive force (Hc) high enough not to affect the heat fluctuation resistance.

Although not illustrated, if the total thickness of the magnetic recording layers exceeds 15 nm, the reversed domain nucleation magnetic field (Hn) decreases. This is because since crystal grains become coarse, a magnetization rotation mode becomes non-simultaneous rotation. Therefore, it is necessary to also consider the thickness of the second magnetic recording layer depending on the thickness of the first magnetic recording layer and the total thickness of the first magnetic recording layer and the second magnetic recording layer is preferably 15 nm or less.

The nonmagnetic substance is described as silicon oxide (SiO₂) in the first embodiment, but may be any substance as long as it is a substance that can form grain boundary portions around magnetic grains so as to suppress or block the exchange interaction between the magnetic grains and that is a nonmagnetic substance not solid-soluble to cobalt (Co). For example, chromium (Cr), oxygen (O), and oxides such as silicon oxide (SiOx), chromium oxide (Cr₂O₃), titanium oxide (TiO₂), and zirconium oxide (ZrO₂) can be cited as examples.

### Second Embodiment

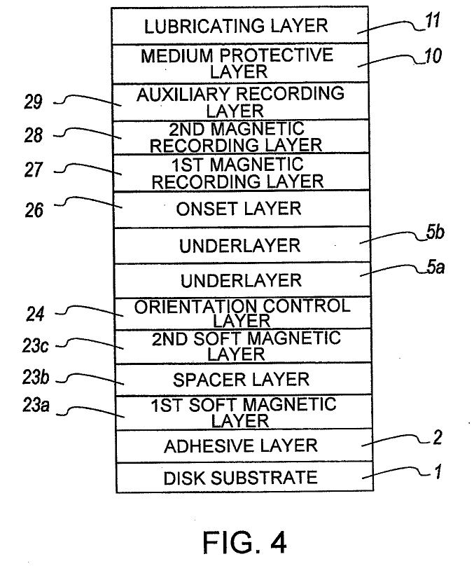

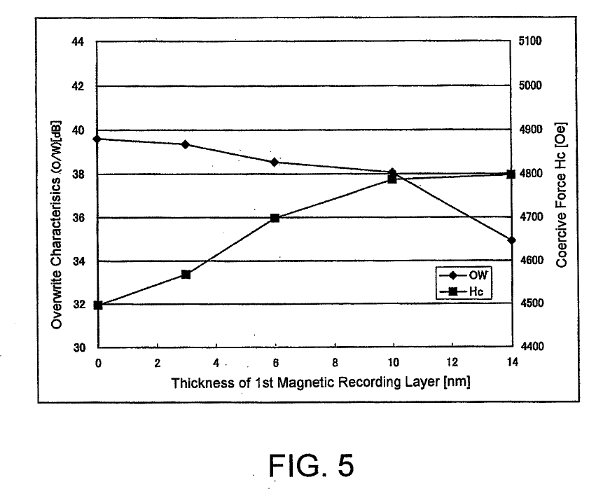

A second embodiment of a perpendicular magnetic recording medium according to this invention will be described with reference to the drawings. FIG. 4 is a diagram for explaining the configuration of the perpendicular magnetic recording medium according to the second embodiment and FIG. 5 is a diagram showing the relationship between overwrite characteristics and coercive force when the thicknesses of first and second magnetic recording layers are changed. The same symbols are assigned to those portions of which description overlaps that of the foregoing first embodiment, thereby omitting explanation thereof.

The perpendicular magnetic recording medium shown in FIG. 4 comprises a disk substrate 1, an adhesive layer 2, a first soft magnetic layer 23a, a spacer layer 23b, a second soft magnetic layer 23c, an orientation control layer 24, an underlayer 5a, an underlayer 5b, an onset layer 26, a first magnetic recording layer 27, a second magnetic recording layer 28, an auxiliary recording layer 29, a medium protective layer 20, and a lubricating layer 21.

A soft magnetic layer is formed by interposing the nonmagnetic spacer layer 23b between the first soft magnetic layer 23a and the second soft magnetic layer 23c so as to have AFC (antiferro-magnetic exchange coupling). With this configuration, magnetization directions of the soft magnetic layer can be aligned along a magnetic path with high accuracy, so that it is possible to reduce noise generated from the soft magnetic layer. Specifically, the composition of the first soft magnetic layer 23a and the second soft magnetic layer 23c is CoCrFeB and the composition of the spacer layer 23b is Ru.

The orientation control layer 24 has a function of protecting the soft magnetic layer 23a to 23c and a function of facilitating alignment of the orientation of crystal grains of the underlayer 5a. The orientation control layer 4 is a layer of NiW or NiCr having an fcc structure.

The onset layer 26 is a nonmagnetic granular layer. By forming the nonmagnetic granular layer on an hcp crystal structure of the underlayer 5b and growing a granular layer of the first magnetic recording layer 27 thereon, the onset layer 26 has a function of separating the magnetic granular layer from an initial stage (buildup). The composition of the onset layer 26 is nonmagnetic CoCr—SiO₂.

Using a hard magnetic target made of CoCrPt containing Cr and chromium oxide (Cr₂O₃) as examples of a nonmagnetic substance, the first magnetic recording layer 27 with an hcp crystal structure of 2 nm was formed. The first magnetic recording layer is preferably set in a range of 7 nm to 15 nm and more preferably 1.5 nm to 3 nm. The composition of the target for forming the first magnetic recording layer 27 is 92 (mol %) CoCr₁₀Pt and 8 (mol %) Cr₂O₃. Therefore, the amount of the nonmagnetic substance contained in the first magnetic recording layer 27 is 10×0.92+8=17.2 (mol %).

Using a hard magnetic target made of CoCrPt containing Cr and titanium oxide (TiO₂) as examples of a nonmagnetic substance, the second magnetic recording layer 28 with an hcp crystal structure of 10 nm was formed. The second magnetic recording layer 28 can be suitably set in a range of 0.5 nm to 5 nm. The composition of the target for forming the second magnetic recording layer 7 is 91 (mol %) CoCr₁₂Pt and 9 (mol %) TiO₂. Therefore, the amount of the nonmagnetic substance contained in the second magnetic recording layer 28 is 12×0.91+9=19.92 (mol %).

That is, given that the content of the nonmagnetic substance in the first magnetic recording layer 27 is A mol % and the content of the nonmagnetic substance in the second magnetic recording layer 28 is B mol %, A<B (the second magnetic recording layer 28 contains more nonmagnetic substance).

The auxiliary recording layer 29 is a thin film (continuous layer) formed on the granular magnetic layer and exhibiting high perpendicular magnetic anisotropy, thereby forming a CGC structure (Coupled Granular Continuous). With this configuration, in addition to the high-density recording characteristics and the low-noise characteristics of the granular layers, it is possible to add high heat resistance of the continuous film. The composition of the auxiliary recording layer 29 is CoCrPtB.

Like in the foregoing first embodiment, the medium protective layer 10 and the lubricating layer 11 were formed on the auxiliary recording layer 29.

For comparison, perpendicular magnetic recording media were manufactured by changing the thickness of the first magnetic recording layer 6 from 0 to 14 nm while the sum of the thicknesses of the first magnetic recording layer 6 and the second magnetic recording layer 7 was set to 14 nm, and the magnetostatic properties of the obtained perpendicular magnetic recording disks were measured and evaluated using the Kerr effect. FIG. 3 shows changes in coercive force (Hc) and overwrite characteristics (O/W) when the ratio between the thicknesses of the first magnetic recording layer 6 and the second magnetic recording layer is changed. When the first magnetic recording layer 6 is 0 nm, the second magnetic recording layer 7 is 14 nm and thus it is shown that substantially only the second magnetic recording layer 7 is formed. Likewise, when the first magnetic recording layer 6 is 14 nm, the second magnetic recording layer 7 is 0 nm and thus it is shown that substantially only the first magnetic recording layer 6 is formed.

As shown in FIG. 5, it is seen that when the ratio between the thicknesses of the first magnetic recording layer 6 and the second magnetic recording layer 7 is changed, the overwrite characteristics and the coercive force change. It is seen that the overwrite characteristics increase as the thickness of the first magnetic recording layer 6 decreases, but, in a specific thickness range, the overwrite characteristics can be improved while maintaining the coercive force.

For example, as compared with the case of only the first magnetic recording layer 6 (when the thickness of the first magnetic recording layer 6 is 14 nm: plot at the right end in the figure), there is a rapid improvement of about 3 [dB] when the thickness of the layer is 10 nm, and thereafter, there is a further improvement of about 2 [dB] toward the thickness of 0 nm. On the other hand, the coercive force Hc slowly decreases by about 10 [Oe] when the thickness of the layer is 10 nm as compared with the case where the thickness of the layer is 14 nm, and thereafter, it further decreases rapidly by about 300 [Oe] toward the thickness of 0 nm. That is, according to FIG. 5, when the thickness of the first magnetic recording layer 6 is around 10 nm, the overwrite characteristics and the coercive force are both high and thus it can be said that such a thickness is the most balanced thickness.

Accordingly, also in the second embodiment, it has been confirmed that, by configuring such that the magnetic recording layers form the two-layer structure and the second magnetic recording layer on the surface layer side contains more nonmagnetic substance and, further, by setting the appropriate ratio of the layer thicknesses, the overwrite characteristics (O/W) can be improved while maintaining the coercive force (Hc) high enough not to affect the heat fluctuation resistance.

While the preferred embodiments of this invention have been described with reference to the accompanying drawings, it is needless to say that this invention is not limited thereto. It is apparent that a person skilled in the art can think of various changes and modifications in the category described in claims and it is understood that those also naturally belong to the technical scope of this invention.

### INDUSTRIAL APPLICABILITY

This invention can be used as a perpendicular magnetic recording medium adapted to be mounted in a perpendicular magnetic recording type HDD (hard disk drive) or the like and as a manufacturing method thereof.

1. A perpendicular magnetic recording disk for use in perpendicular magnetic recording, comprising at least an underlayer, a first magnetic recording layer, and a second magnetic recording layer on a substrate in the order named, wherein:
said first magnetic recording layer and said second magnetic recording layer are each a ferromagnetic layer of a granular structure containing a nonmagnetic substance forming a grain boundary portion between crystal grains containing at least cobalt (Co), and
given that the content of said nonmagnetic substance in said first magnetic recording layer is A mol % and the content of said nonmagnetic substance in said second magnetic recording layer is B mol %, A<B.

2. The perpendicular magnetic recording disk according to claim 1, wherein the content of said nonmagnetic substance in said first magnetic recording layer or said second magnetic recording layer is 8 mol % to 20 mol %.

3. The perpendicular magnetic recording disk according to claim 1, wherein the total thickness of said first magnetic recording layer and said second magnetic recording layer is 15 nm or less.

4. The perpendicular magnetic recording disk according to claim 1, wherein an orientation control layer having an amorphous or fcc structure is provided between said substrate and said underlayer.

5. The perpendicular magnetic recording disk according to claim 1, wherein an amorphous soft magnetic layer is provided between said substrate and said underlayer.

6. The perpendicular magnetic recording disk according to claim 1, wherein said substrate is an amorphous glass.

7. The perpendicular magnetic recording disk according to claim 1, wherein said nonmagnetic substance contains chromium (Cr), oxygen, or an oxide.

8. A method of manufacturing a perpendicular magnetic recording disk for use in perpendicular magnetic recording, said disk comprising at least an underlayer, a first magnetic recording layer, and a second magnetic recording layer on a substrate in the order named, said method comprising:
forming, as said first magnetic recording layer, a ferromagnetic layer of a granular structure in which a nonmagnetic substance is segregated between magnetic grains containing at least cobalt (Co), and
forming, as said second magnetic recording layer, a ferromagnetic layer of a granular structure in which a nonmagnetic substance is segregated between magnetic grains containing at least cobalt (Co),
wherein, given that the content of said nonmagnetic substance in said first magnetic recording layer is A mol % and the content of said nonmagnetic substance in said second magnetic recording layer is B mol %, A<B.
